(19) United States
(12) Patent Application Publication
(10) Pub. No.: US 2006/0024929 A1
(43) Pub. Date: Feb. 2, 2006

(54) Method of forming a well in a substrate of a transistor of a semiconductor device

(75) Inventor: Myoung-Soo Kim, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/170,944

(22) Filed: Jun. 30, 2005

(30) Foreign Application Priority Data
Jul. 27, 2004 (KR) 2004-58626

(51) Int. Cl. H01L 21/337; H01L 21/425

(52) U.S. Cl. 438/516; 438/194

(57) ABSTRACT

In a method of forming a well in a substrate of a transistor of a semiconductor device without an out-diffusion of impurities from the substrate, a first conductivity type impurity is implanted into the substrate. A second conductivity type impurity, which is opposite to the first conductivity type impurity, is implanted into a portion of the substrate, thereby forming a first conductivity type impurity region and a second conductivity type impurity region in the substrate. A diffusion barrier layer is formed on the substrate for preventing the first and second conductivity type impurities from being diffused out of the substrate. The substrate is heat-treated for diffusing the first and second conductivity type impurities from the first and second conductivity type impurity regions, respectively, thereby forming a first conductivity type well and a second conductivity type well in the substrate. Accordingly, an out-diffusion of the impurities from the substrate is minimized or prevented in the formation of the well.

### CROSS-REFERENCE TO RELATED APPLICATION

This application claims priority to Korean Patent Application No. 2004-58626, filed on Jul. 27, 2004, the content of which is hereby incorporated by reference in its entirety.

### BACKGROUND OF THE INVENTION

1. Field of the Invention

The present invention relates to a method of forming a well in a substrate of a transistor of a semiconductor device. More particularly, the present invention relates to a method of forming a well in a substrate of a transistor of a semiconductor device without an out-diffusion of impurities, and to a method of manufacturing a semiconductor device having the well.

2. Description of the Related Art

In a typical high-voltage apparatus, an input/output circuit includes high-voltage devices and a logic circuit includes low-voltage devices. Generally a breakdown voltage and a threshold voltage are provided as device characteristics of high- and low-voltage devices. As used herein, “threshold voltage” refers to the gate-to-source voltage at which a transistor starts to conduct current. It is possible during semiconductor device fabrication to use ion implantation in the channel regions to adjust the threshold voltages, in accordance with the characteristics of the high- or low-voltage device.

Integrated circuits consisting of complementary metal oxide semiconductor (CMOS) transistors, commonly referred to as CMOS integrated circuits, are the basis for most digital electronic devices. The CMOS transistor includes both an N type transistor and a P type transistor on the same substrate material. To accommodate both N type and P type transistors on the same substrate, the conventional CMOS integrated circuit manufacturing process includes forming an N-well in a P type substrate or, alternatively, a P-well in an N type substrate. It can be preferable to employ dual-well CMOS technology, which involves forming a first conductivity type well that is opposite to the substrate conductivity type and forming a second conductivity type well of the same conductivity type as the substrate for device optimization.

A voltage of about 10V or greater can be applied to a transistor in a high-voltage semiconductor device, requiring that a drain junction of the transistor in the high-voltage device be formed at a deeper depth than a drain junction of a transistor in a low-voltage device. Accordingly, in a high-voltage device, the N-well or P-well corresponding to drain region of the transistor is of a deeper depth than that of a transistor in a low-voltage device. Generally, a low-concentration impurity is formed in the N-well or P-well where the channel region and the drain region will be formed, for reducing a leakage current. In other words, the fabrication of a transistor in a high-voltage device requires forming a deep well having a low concentration of impurities.

In a conventional method of forming a deep well having a low concentration of impurities, the impurities are implanted into a substrate at high energy, and then a high-temperature heat treatment is performed on the substrate for diffusing the implanted impurities, which is well known in the art as a “drive-in” diffusion process. As a result of the drive-in process, the implanted impurities are diffused in all directions in the substrate, such that the concentration of impurities at the surface portions of the substrate is increased and the depth of the well is increased. However, in the conventional drive-in process, the implanted impurities are diffused towards the surface portion of the substrate, and can escape from the substrate and penetrate into a device structure on the substrate. That is, the implanted impurities can be out-diffused out of the substrate and cause damage to a device structure on the substrate. For example, P type impurities such as boron (B) are easily out-diffused out of a buffer oxide layer on the substrate, whereas N type impurities such as phosphorus (P) have a strong tendency to be captured by the buffer oxide layer.

The out-diffusion of the impurities changes a desired concentration of the impurities in the well, thereby deteriorating electrical characteristics of the CMOS transistor. In addition, the out-diffused impurities contaminate the apparatus for performing the drive-in process, and said contamination results in reduced yield.

In view of the foregoing, a need exists for a method of minimizing or preventing an out-diffusion of impurities during a drive-in diffusion process. A need also exists for a method of minimizing or preventing the contamination of a processing apparatus when performing a drive-in diffusion process.

### SUMMARY OF THE INVENTION

Exemplary embodiments of the present invention generally include methods of forming a well in a substrate of a transistor of a semiconductor device such that an out-diffusion of impurities and contamination of the processing apparatus is minimized or prevented.

Exemplary embodiments of the present invention include a method of manufacturing a semiconductor device employing the method of forming a well such that an out-diffusion of impurities and contamination of the processing apparatus are minimized or prevented.

In accordance with an exemplary embodiment of the present invention, a first conductivity type impurity is implanted into a substrate, and a second conductivity type impurity is implanted into a portion of the same substrate, thereby forming a first conductivity type impurity region and a second conductivity type impurity region in the substrate. The second conductivity type impurity is opposite in electrical charge to the first conductivity type impurity. A diffusion barrier layer is formed on the substrate for preventing an out-diffusion of the first and second conductivity type impurities from the substrate. Then, the substrate is heat-treated for diffusing the first and second conductivity type impurities from the first and second conductivity type impurity regions, respectively, thereby forming a first conductivity type well and a second conductivity type well in the substrate.

According to another exemplary embodiment of the present invention, a first conductivity type impurity is implanted into a substrate, and a diffusion barrier layer is formed on the substrate for preventing an out-diffusion of the first conductivity type impurity from the substrate. After forming the diffusion barrier layer, a second conductivity type impurity is implanted into a portion of the substrate, thereby forming a first conductivity type impurity region and a second conductivity type impurity region in the substrate. The second conductivity type impurity is opposite in charge to the first conductivity type impurity. The substrate is heat-treated for diffusing the first and second conductivity type impurities from the first and second conductivity type impurity regions, respectively, thereby forming a first conductivity type well and a second conductivity type well in the substrate.

In accordance with another exemplary embodiment of the present invention, a diffusion barrier layer is formed on the substrate for preventing an out-diffusion of impurities from the substrate. After the diffusion barrier layer is formed, a first conductivity type impurity is implanted into the substrate including the diffusion barrier layer, and a second conductivity type impurity is implanted into a portion of the substrate, thereby forming a first conductivity type impurity region and a second conductivity type impurity region in the substrate. The second conductivity type impurity is opposite in charge to the first conductivity type impurity. Then, the substrate is heat-treated for diffusing the first and second conductivity type impurities from the first and second conductivity type impurity regions, respectively, thereby forming a first conductivity type well and a second conductivity type well in the substrate.

According to yet another exemplary embodiment of the present invention, a first conductivity type impurity is implanted into a substrate, and a second conductivity type impurity is implanted into a portion of the substrate, thereby forming a first conductivity type impurity region and a second conductivity type impurity region in the substrate. The second conductivity type impurity is opposite in charge to the first conductivity type impurity. A diffusion barrier layer is formed on the substrate for preventing an out-diffusion of the first and second conductivity type impurities the substrate. The substrate is heat-treated for diffusing the first and second conductivity type impurities from the first and second conductivity type impurity regions, respectively, thereby forming a first conductivity type well and a second conductivity type well in the substrate. Then, the second conductivity type impurity is re-implanted into an upper portion of the first conductivity type well in the substrate, and the substrate is additionally heat-treated for diffusing the re-implanted second conductivity type impurity, thereby forming a second conductivity type pocket well in the first conductivity type well. A plurality of transistors is formed on the substrate corresponding to the second conductivity type well, the first conductivity type well, and the second conductivity type pocket well, respectively.

According to various exemplary embodiments of the invention, the diffusion barrier layer is formed prior to the heat-treatment process for a deep well having a low concentration of impurities, thereby minimizing or preventing an out-diffusion of the impurities from the substrate. As a result, the concentration of the impurities in the well is maintained unchanged or substantially unchanged, thereby preventing or minimizing deterioration of electrical characteristics of the transistor.

### BRIEF DESCRIPTION OF THE DRAWINGS

The above-described exemplary embodiments and other features, aspects, and advantages of the present invention will become readily apparent from the following detailed description of the exemplary embodiments when considered in conjunction with the accompanying drawings of which:

FIGS. 1 to 6 are cross-sectional views illustrating various steps of a method of forming a well of a semiconductor device in accordance with an exemplary embodiment of the present invention.

FIG. 7 is a graph illustrating the relationship between the concentration of impurities and depth of a well after ion implantation, and the relationship between the concentration of impurities and depth of the well after a drive-in process in accordance with an exemplary embodiment of the present invention.

FIGS. 8 to 10 are cross-sectional views showing various steps of a method of forming a well of a semiconductor device according to an exemplary embodiment of the present invention.

FIGS. 11 to 13 are cross-sectional views illustrating various steps of a method of forming a well of a semiconductor device according to an exemplary embodiment of the present invention.

FIGS. 14 to 17 are cross-sectional views illustrating various steps of a method of manufacturing a semiconductor device according to an exemplary embodiment of the present invention.

### DETAILED DESCRIPTION OF EXEMPLARY EMBODIMENTS

The present invention will be described more fully hereinafter with reference to the accompanying drawings in which exemplary embodiments of the present invention are shown. As used herein, “substrate” includes a variety of structures such as semiconductor device structures. A substrate can be a single layer of material, such as a silicon wafer, or can include any number of layers.

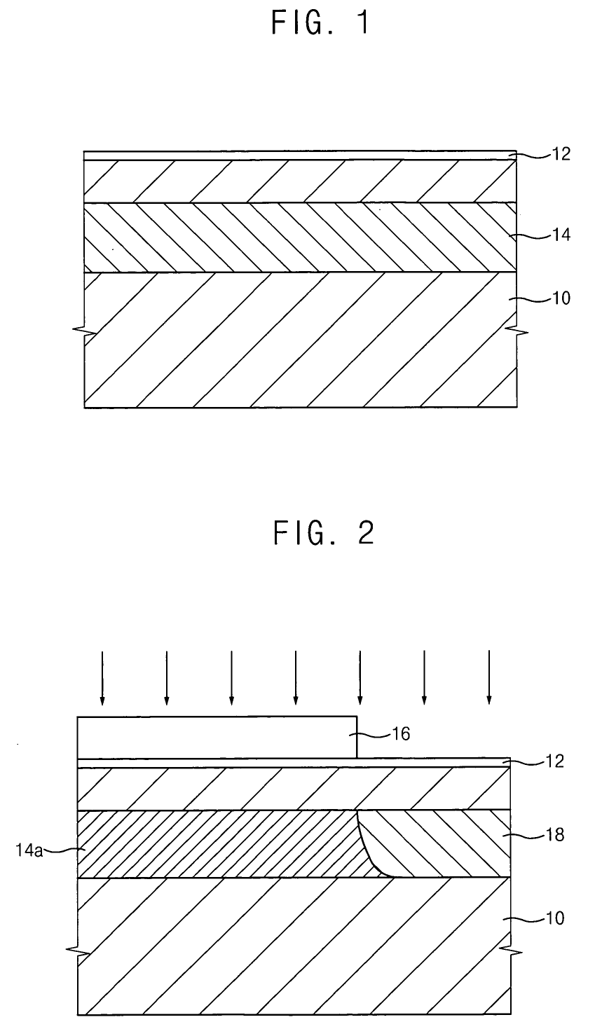

FIGS. 1 to 6 are cross-sectional views illustrating various steps of a method of forming a well of a semiconductor device in accordance with an exemplary embodiment of the present invention.

As FIG. 1 depicts, a buffer oxide layer 12 is formed entirely over a semiconductor substrate 10 such as a silicon wafer. Preferably, the buffer oxide layer 12 has a thickness of about 50 Å to about 200 Å. In accordance with various embodiments of the invention, the substrate 10 is predoped with P type impurities throughout the entire substrate 10. It should be understood that different P type impurities can be implanted, including, but not limited to, boron (B).

In accordance with the various exemplary embodiments of the present invention, the buffer oxide layer 12 is formed to prevent damage to the substrate 10 in a subsequent ion implantation process.

After the buffer oxide layer 12 is formed, N type impurities are implanted into the substrate 10 including the buffer oxide layer 12. Preferably, the N type impurities are implanted in a substantially vertical direction relative to a surface of the substrate 10. In the present embodiment, the N type impurities are implanted at a deep depth in the substrate 10 for forming a deep well having a low concentration of impurities, such that an N type impurity region 14 is formed at a deep depth in the substrate 10.

As shown in FIG. 2, a first photoresist pattern 16 is formed on the substrate 10 including the buffer oxide layer 12 and serves as a mask for the ion implantation process in which P type impurities 13 are implanted into the substrate 10. Preferably, the P type impurities are implanted in a substantially vertical direction relative to a surface of the substrate 10. According to various exemplary embodiments of the present invention, the P type impurities are implanted into the exposed substrate 10 including the buffer oxide layer 12, through the first photoresist pattern 16, under the implantation conditions that a first P type impurity region 18 is formed within the substrate 10 to the same depth as the N type impurity region 14. That is, the portion of the N type impurity region 14 that is not masked by the first photoresist pattern 16 is rendered by the ion implantation process into the first P type impurity region 18 in the substrate 10. An example of a P type impurity suitable for implementing the present invention is boron (B).

Hereinafter, the N type impurity region 14 defined by the first P type impurity region 18 is designated as a reference numeral 14a.

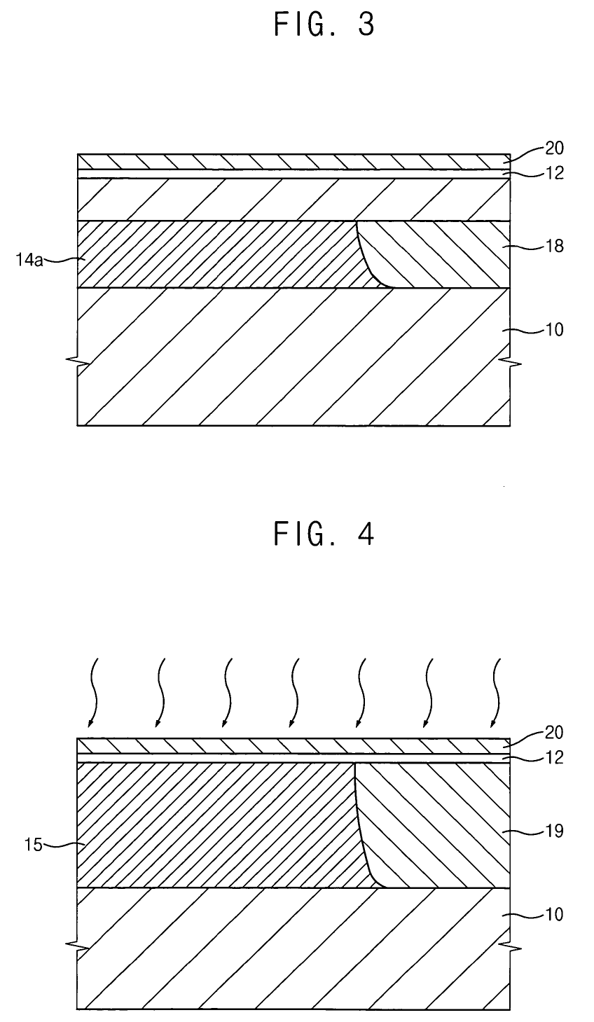

As shown in FIG. 3, after the first photoresist pattern 16 is removed, a silicon nitride layer 20 is formed on the buffer oxide layer 12 for preventing an out-diffusion of the P type impurities from the substrate 10. That is, the silicon nitride layer 20 functions as a diffusion barrier layer. Preferably, the silicon nitride layer 20 is formed to a thickness of about 50 Å to about 3000 Å through a chemical vapor deposition (CVD) process. It is undesirable when the silicon nitride layer 20 to be formed to a thickness of less than about 50 Å, because the P type impurities are diffused out of the substrate 10. Further, it is undesirable when the silicon nitride layer 20 is formed to a thickness of greater than about 3000 Å, because other impurities can no longer be implanted into the substrate 10 in a subsequent process.

Referring to FIG. 4, in an exemplary embodiment of the invention, a heat treatment 21 is performed on the substrate 10 including the implanted P type and N type impurities. Preferably, the heat treatment or drive-in diffusion process is performed on the substrate 10 such that the P type and the N type impurities therein are diffused in all directions within the substrate 10. After the drive-in diffusion process, the P type and the N type impurities are diffused into regions in proximity to a surface portion of the substrate 10. Accordingly, as shown in FIG. 4, a P-well 19 including the P type impurities and an N-well 15 including the N type impurities are formed in the substrate 10.

Since the P type impurities are already implanted into the entire substrate 10, when the in-drive diffusion process is performed the P-well 19 has a higher concentration of impurities than other portions of the substrate 10. Preferably, the N-well 15 and the P-well 19 are formed to a depth of about 1 μm to about 12 μm. In at least one exemplary embodiment, a high-voltage device is formed on the substrate 10 corresponding to the N-well 15, and a logic circuit is formed on the substrate 10 corresponding to the P-well 19. It should be appreciated that different types of semiconductor devices can be formed on the substrate 10.

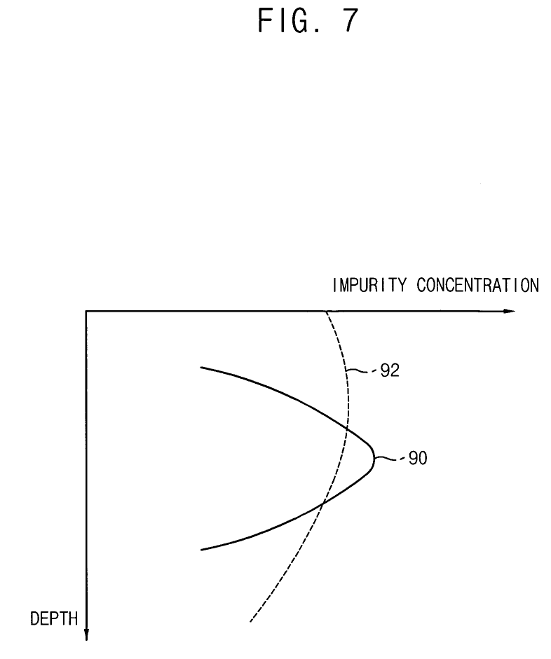

FIG. 7 is a graph illustrating the relationship between the concentration of impurities and depth of a well after ion implantation, and the relationship between the concentration of impurities and depth of the well after a drive-in process in accordance with an exemplary embodiment of the present invention. As FIG. 7 depicts, the concentration of impurities after ion implantation is a first function 90 of the well depth in the substrate 10, whereas the concentration of impurities after the drive-in diffusion process is a second function 92 (shown as a broken line) of the well depth in the substrate 10.

According to various exemplary embodiments of the invention, when the ion implantation process is completed, the impurities are accumulated at a particular region in the substrate 10, such that the impurity region is very narrow in width and has a very high concentration of impurities. When the drive-in diffusion process is completed, the impurities in the substrate 10 are diffused in all directions, such that the impurity region is wider and a depth of the impurity region increased, while the concentration of impurities is decreased. However, the concentration of impurities at the surface portion of the substrate 10 is increased. Accordingly, as a result of the processing conditions of the drive-in process, the depth of the well is sufficiently increased and the concentration of impurities is sufficiently reduced in accordance with the characteristics of a desired transistor.

In FIG. 7, the relationships are based on a drive-in diffusion process performed in a furnace for heat treating a substrate in a nitrogen atmosphere at a temperature of about 800° C. to about 1300° C. for about 70 minutes. In general, variations in the drive-in diffusion processing conditions affect the relationships between the concentration of impurities and the well depth. According to various exemplary embodiments of the invention, the processing conditions of the drive-in process are controlled in accordance with electrical characteristics of a desired transistor.

In accordance with the exemplary embodiments of the invention, the silicon nitride layer 20 prevents an out-diffusion of the implanted impurities from the substrate 10. Accordingly, an out-diffusion of the implanted impurities is minimized or prevented, even though the impurities are largely diffused toward the surface of the substrate 10 in the drive-in process. In addition, since the P type impurities are partially implanted into the exposed substrate 10 after the N type impurities are already implanted into the entire substrate 10, the N-well 15 and the P-well 19 are formed at a desired position in the substrate 10.

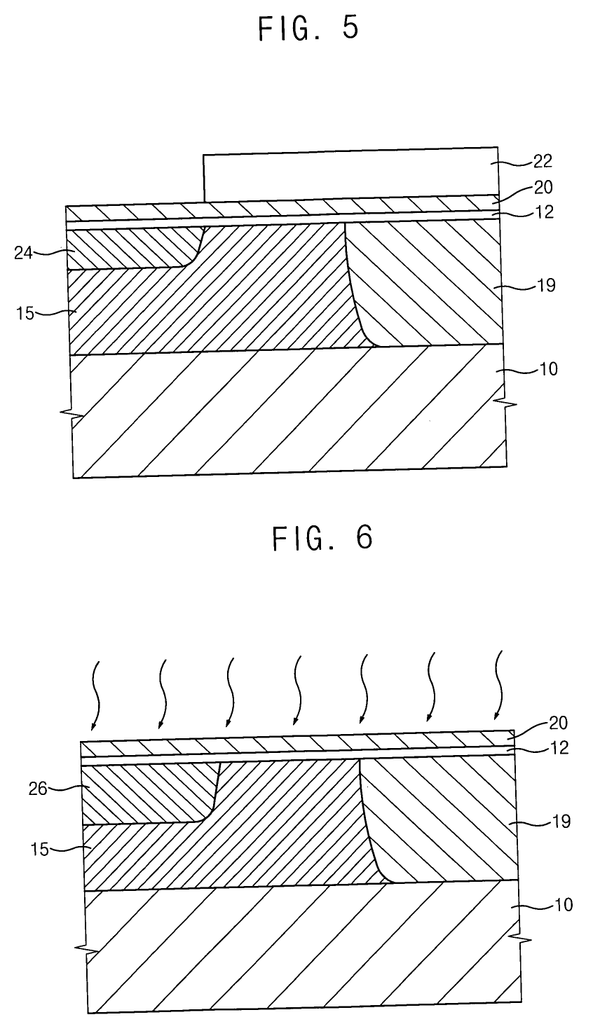

As shown in FIG. 5, a second photoresist pattern 22 is formed on the substrate 10 including the silicon nitride layer 20. According to various exemplary embodiments of the invention, the second photoresist pattern 22 is formed to selectively expose a portion of the surface of the substrate 10 corresponding to a portion of the N-well 15. Then, P type impurities are implanted into the substrate 10 using the second photoresist pattern 22 as an ion implantation mask. Preferably, the P type impurities are implanted in a substantially vertical direction relative to a surface of the substrate 10. In accordance with the present embodiment, the second P type impurities are implanted into the substrate 10, using the second photoresist pattern 22 as an ion implantation mask, under the implantation conditions such that a second P type impurity region 24 is formed in the substrate 10 to a shallower depth than that of the N-well 15. As FIG. 5 depicts, an upper portion of the N-well 15 is rendered by the ion implantation process into the second P type impurity region 24, and the second P type impurity region 24 defines the N-well 15 in the substrate 10.

As shown in FIG. 6, after removing the second photoresist pattern 22, a drive-in diffusion process 23 is performed on the substrate 10 including silicon nitride layer 20, and the implanted P type impurities are diffused in all directions in the N-well 15. Accordingly, a pocket P-well 26 is formed in the N-well 15 adjacent to the surface of the substrate 10. In the present embodiment, the drive-in process for forming the pocket P-well 26 is performed in a furnace for a heat treatment in a nitrogen atmosphere at a temperature of about 800° C. to about 1300° C. for about 70 minutes. As described above, variations in the processing conditions cause a change of the function between the concentration of impurities and the well depth in the pocket P-well 26. In various exemplary embodiments of the present invention, the processing conditions of the drive-in process are controlled in accordance with characteristics of a desired transistor.

The silicon nitride layer 20 prevents the impurities in the second P type impurity region 24 from being diffused out of the substrate 10, so that an out-diffusion of the P type impurities is minimized, even though the P type impurities in the second P type impurity region 24 are largely diffused toward the surface of the substrate 10 in the drive-in process.

The substrate 10 is cleaned using a cleaning solution. Preferable, the cleaning solution includes an aqueous HF solution. A stripping process is performed on the substrate 10, by which the silicon nitride layer 20 is removed from the substrate 10. According to the present embodiment, out-diffusing of the impurities is substantially prevented during the formation of the well of a high-voltage device.

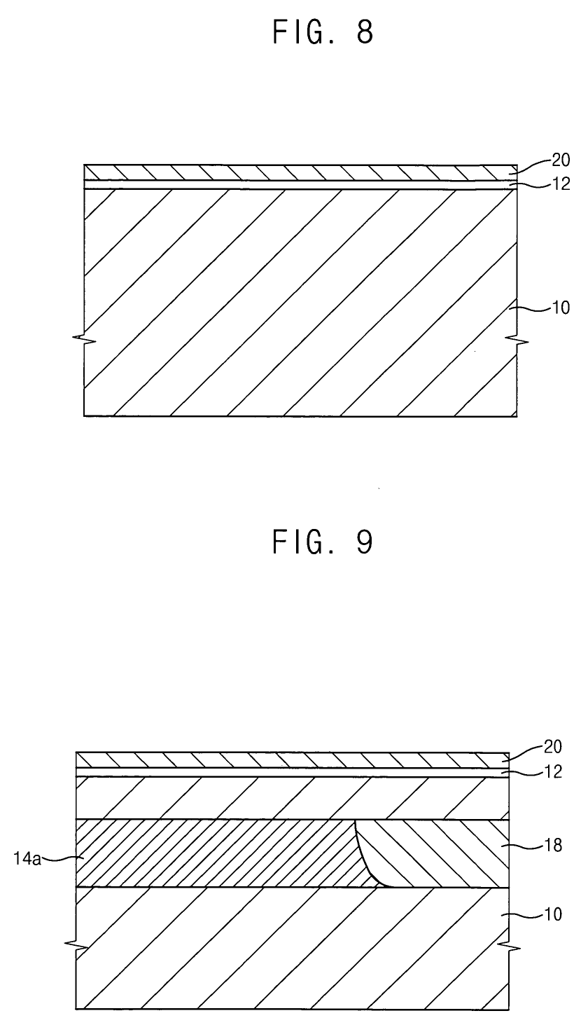

FIGS. 8 to 10 are cross-sectional views illustrating various steps of a method of forming a well of a semiconductor device according to an exemplary embodiment of the present invention.

As shown in FIG. 8, a buffer oxide layer 12 is formed on a semiconductor substrate 10, such as a silicon wafer. Preferably, buffer oxide layer 12 is formed to a thickness of about 50 Å to about 200 Å. A silicon nitride layer 20 is formed on the buffer oxide layer 12 for preventing an out-diffusion of the P type impurities from the substrate 10. The silicon nitride layer 20 acts as a diffusion barrier layer in the present embodiment, as described above. Preferably, the diffusion barrier layer is formed to a thickness of about 50 Å to about 3000 Å through a chemical vapor deposition (CVD) process.

Referring to FIG. 9, N type impurities are implanted into the substrate 10 including the buffer oxide layer 12 and the silicon nitride layer 20. Preferably, the N type impurities are implanted in a substantially vertical direction relative to a surface of the substrate 10, thereby forming a deep N type impurity region (not shown) in the substrate 10. Then, P type impurities are implanted into a portion of the substrate 10. Preferably, the P type impurities are implanted in a substantially vertical direction relative to the surface of the substrate 10. In the present embodiment, the P type impurities are implanted into the portion of the substrate 10 under the implantation conditions that a P type impurity region 18 is formed in the substrate 10 to the same depth as the N type impurity region 14a. Accordingly, a portion of the N type impurity region 14a is rendered by the ion implantation process into the P type impurity region 18, and the P type impurity region 18 defines the N type impurity region in the substrate 10. A defined N type impurity region is designated as a reference numeral 14a in FIG. 9.

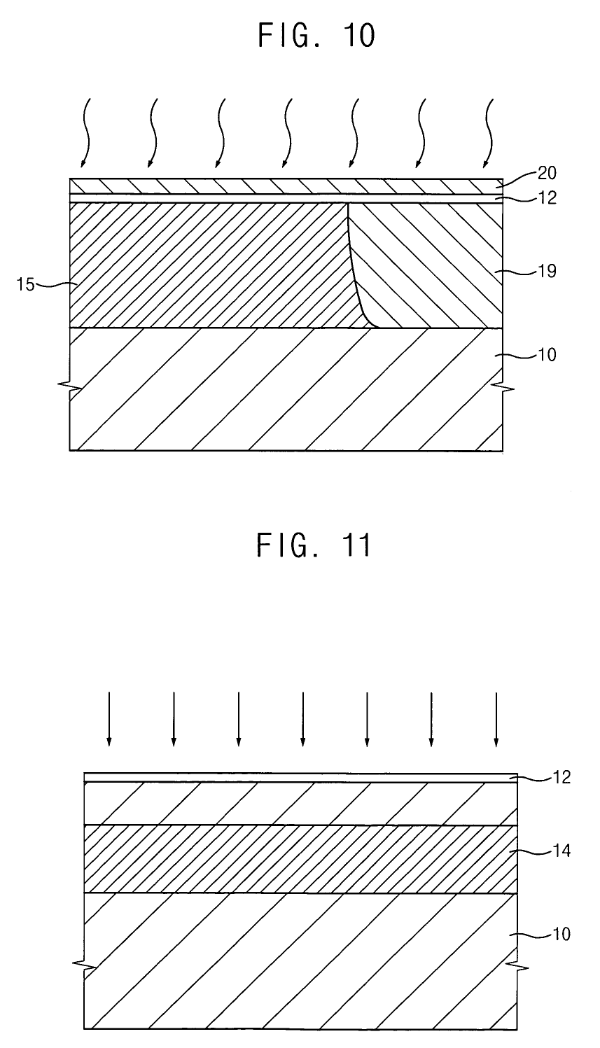

Referring to FIG. 10, a heat treatment, which is well known as a drive-in process in the art, is performed on the substrate 10 in which the P type and the N type impurities are implanted, so that the P type and the N type impurities are diffused in all directions in the substrate 10. Accordingly, the P type and the N type impurities are diffused near a surface portion of the substrate 10, so that a P-well 19 including the P type impurities and an N-well 15 including the N type impurities are formed under the surface of the substrate 10. The drive-in diffusion process is performed in a furnace for a heat treatment in a nitrogen atmosphere at a temperature of about 800° C. to about 1300° C. for about 70 minutes.

Then, as described above with reference to FIGS. 5 and 6, P type impurities are secondarily implanted into a portion of the substrate 10 corresponding to the N-well 15, vertically with respect to the surface of the substrate 10. A drive-in diffusion process is again performed on the substrate 10 in which the P type impurities are again implanted, and the P type impurities are diffused in all directions in the N-well 15. Accordingly, a pocket P-well 26 is formed in the N-well 15 under the surface of the substrate 10. In the present embodiment, the drive-in process for the pocket P-well 26 is performed in a furnace for a heat treatment in a nitrogen atmosphere at a temperature of about 800° C. to about 1300° C. for about 70 minutes.

The substrate 10 is cleansed using a cleaning solution including an aqueous HF solution, and a stripping process is performed on the substrate 10. Accordingly, the silicon nitride layer 20 is removed from the substrate 10. The silicon nitride layer 20 prevents the impurities in the second P type impurity region 24 from being diffused out of the substrate 10, so that an out-diffusion of the P type impurities is minimized, even though the P type impurities in the P type impurity region are largely diffused toward the surface of the substrate 10 in the drive-in process. According to the present embodiment, out-diffusion of the impurities is sufficiently prevented during the formation of the well of a high voltage device. FIGS. 11 to 13 are cross-sectional views illustrating various steps of a method of forming a well in a substrate of a semiconductor device according to an exemplary embodiment of the present invention.

As shown in FIG. 11, a buffer oxide layer 12 is formed on a semiconductor substrate 10, such as a silicon wafer. In at least one embodiment of the invention, the buffer layer 12 is formed to a thickness of about 50 Å to about 200 Å. The substrate 10 is already doped with P type impurities throughout the entire substrate 10. N type impurities 15 are implanted into the substrate 10 including the buffer oxide layer 12. In at least one embodiment of the invention, the N type impurities are implanted in a substantially vertical direction relative to a surface of the substrate 10, thereby forming an N type impurity region 14 at a deep depth in the substrate 10.

As shown in FIG. 12, a silicon nitride layer 20 is formed on the buffer oxide layer 12 for preventing the P type impurities from being diffused out of the substrate 10. The silicon nitride layer 20 functions as a diffusion barrier layer, as described above. In at least one embodiment of the invention, the silicon nitride layer 20 is formed to a thickness of about 50 Å to about 3000 Å through a chemical vapor deposition (CVD) process.

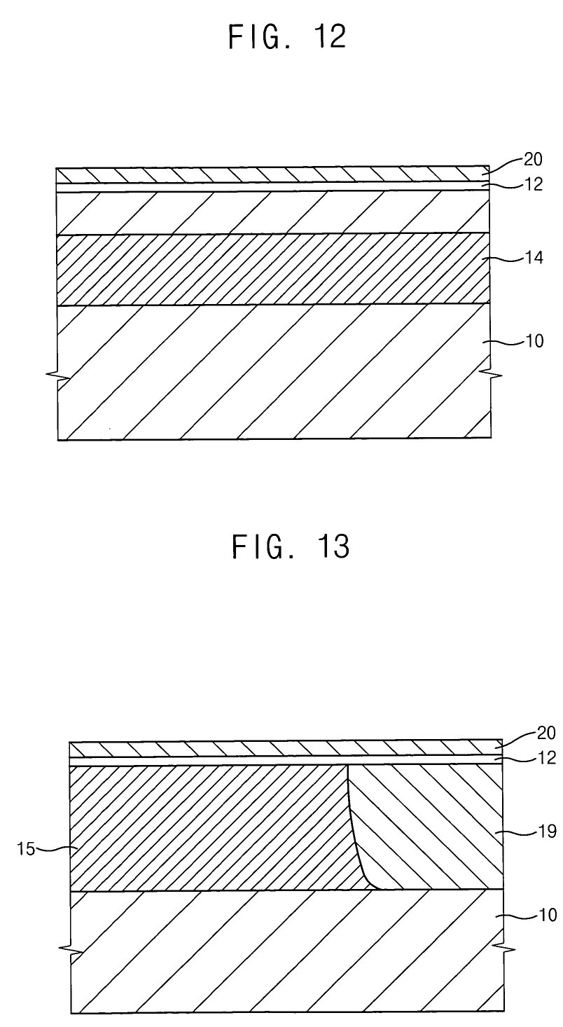

Referring to FIG. 13, P type impurities are implanted into a portion of the substrate 10. Preferably, the P type impurities are implanted in a substantially vertical direction relative to the surface of the substrate 10. The P type impurities are implanted into the portion of the substrate 10 under the implantation conditions that a P type impurity region (not shown) is formed in the substrate 10 to the same depth as the N type impurity region 14. Accordingly, a portion of the N type impurity region 14 is rendered by the ion implantation process into the P type impurity region, and the P type impurity region defines the N type impurity region 14 in the substrate 10.

Then, a drive-in process is performed on the substrate 10 such that the implanted P type and the N type impurities are diffused in all directions in the substrate 10. Accordingly, the P type and the N type impurities are diffused in proximity to a surface portion of the substrate 10, such that a P-well 19 including the P type impurities and an N-well 15 including the N type impurities are formed adjacent to the surface of the substrate 10. In at least one embodiment of the invention, the drive-in process is performed in a furnace for a heat treatment in a nitrogen atmosphere at a temperature of about 800° C. to about 1300° C. for about 70 minutes.

Subsequently, as described above with reference to FIGS. 5 and 6, P type impurities are implanted into a portion of the substrate 10 corresponding to a portion of the N-well 15. In at least one embodiment of the invention, the P type impurities are implanted in a substantially vertical direction relative to a surface of the substrate 10. A drive-in process is again performed on the substrate 10 in which the P type impurities are again implanted. Using a drive-in process, the P type impurities are diffused in all directions in the N-well 15. Accordingly, a pocket P-well 26 is formed in the N-well 15 adjacent to the surface of the substrate 10. In the present embodiment, the drive-in process for the pocket P-well 26 is performed in a furnace for a heat treatment in a nitrogen atmosphere at a temperature of about 800° C. to about 1300° C. for about 70 minutes.

The substrate 10 is cleansed using a cleaning solution including an aqueous HF solution. It should be appreciated that any means for cleaning the substrate 10 should be suitable for implementing the invention. A stripping process is performed on the substrate 10. Accordingly, the silicon nitride layer 20 is removed from the substrate 10. The silicon nitride layer 20 prevents an out-diffusion of the impurities in the second P type impurity region 24 from the substrate 10, so that an out-diffusion of the P type impurities is minimized or prevented, even though the P type impurities in the P type impurity region are largely diffused toward the surface of the substrate 10 in the drive-in process. According to the present embodiment, out-diffusion of the impurities is sufficiently prevented during the formation of the well of a high voltage device.

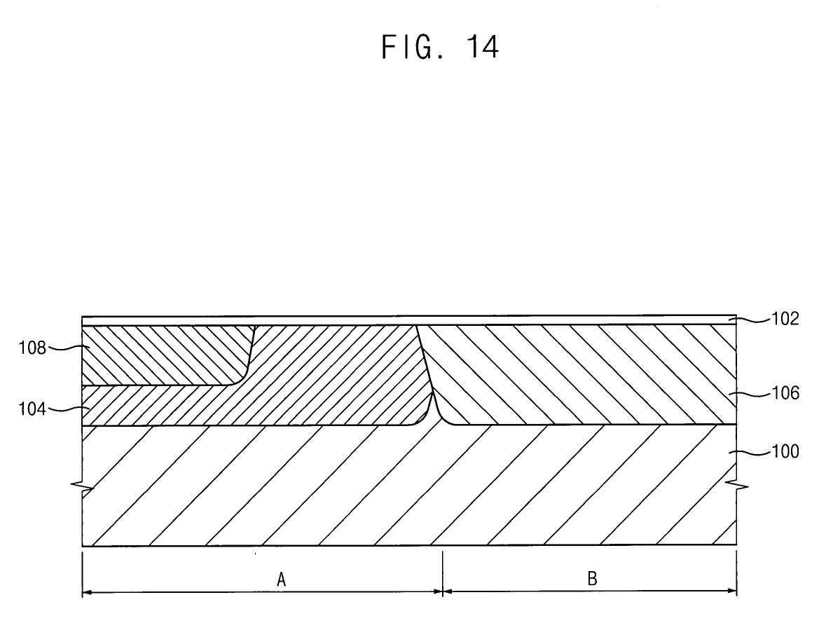

FIGS. 14 to 17 are cross-sectional views illustrating various steps of a method of manufacturing a semiconductor device according to an exemplary embodiment of the present invention.

Referring to FIG. 14, a high-voltage device region A and a logic circuit region B are formed on a surface of the substrate 100 in which P type impurities are already implanted. In the same method as described above with reference to FIGS. 1 to 4, an N-well 104 is formed under a surface of the substrate 100 of the high-voltage region A, and a P-well 106 is formed adjacent to a surface of the substrate 100 of the logic circuit region B. Preferably, the N-well 104 and the P-well 106 are formed to a depth of about 1 μm to about 12 μm through ion implantation and a drive-in process.

In the manner described above with reference to FIG. 5, P type impurities are secondarily implanted into a portion of the substrate 100 corresponding to a portion of the N-well 104. Preferably, the P type impurities are implanted in a substantially vertical direction in relation to a surface of the substrate 10. An NMOS transistor of the high-voltage device is to be formed on the portion of the substrate 100 corresponding to the portion of the N-well 104. The P type impurities are implanted into the portion of the substrate 100 corresponding to the portion of the N-well 104 under the implantation conditions that a second P type impurity region (not shown) is formed in the substrate 100 to a shallower depth than that of the N-well 104. Accordingly, an upper portion of the N-well 104 is rendered the second P type impurity region, and the second P type impurity region defines the N-well 104 in the substrate 100.

A drive-in diffusion process is performed on the substrate 100 in which the P type impurities are again implanted, and the P type impurities in the second P type impurity region are diffused in all directions in the N-well 104. Accordingly, a pocket P-well 108 is formed in the N-well 104 under the surface of the substrate 100.

Thereafter, a silicon nitride layer (not shown), which was formed on the buffer oxide layer 102 for preventing an out-diffusion of the impurities, is removed from the substrate 100. The silicon nitride layer may be removed not in the present step but in a next step, as would be known to those skilled in the art. In various exemplary embodiments of the present invention, a PMOS transistor is formed on the region of substrate 100 corresponding to the N-well 104, and an NMOS transistor is formed on the region of substrate 100 corresponding to the P-well 108.

An out-diffusion of the P type impurities from the substrate 100 is prevented by the silicon nitride layer on the buffer oxide layer 102 during the drive-in diffusion process for forming the N-well 104, the P-well 106, and the pocket P-well 108.

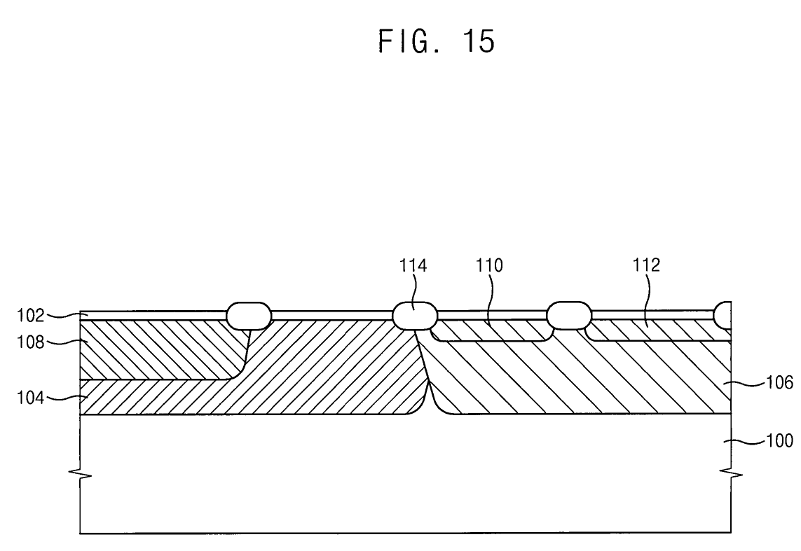

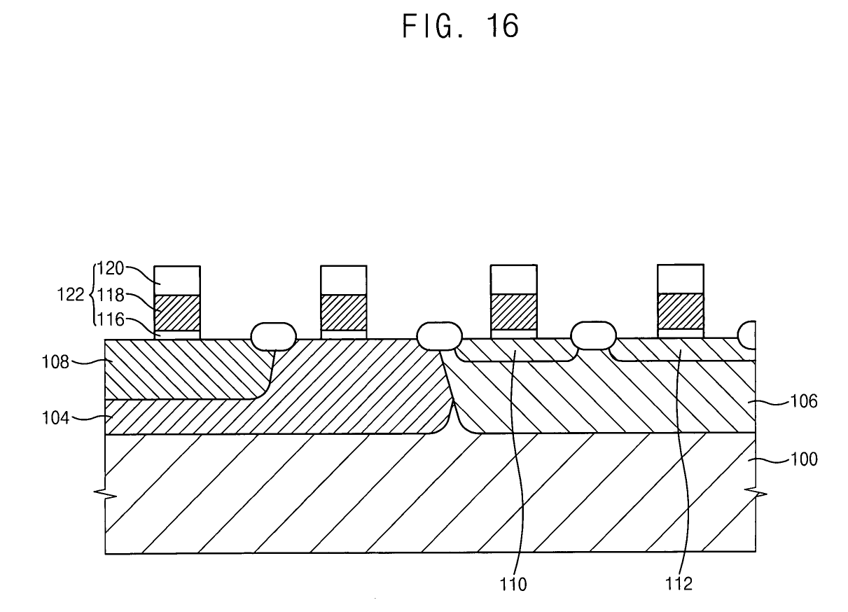

As shown in FIG. 15, a logic N-well 110 and a logic P-well 112 are formed on a substrate 100 corresponding to the P-well 106. A logic circuit (not shown) including a plurality of CMOS transistors is formed in the logic N-well 110 and the logic P-well 112. In at least one exemplary embodiment of the invention, the logic N-well 110 and the logic P-well 112 are formed as a retrograde well in which the concentration of impurities is not changed with respect to a well depth. Impurities are implanted into the substrate 100 with a high-energy condition, thereby forming a lower portion of the retrograde well, and impurities are implanted into the substrate 100 with a low-energy and a low-current condition, thereby forming an upper portion of the retrograde well.

In the present embodiment, the logic N-well 110 and the logic P-well 112 have a depth shallower than that of the N-well 104 and the pocket P-well 108 in which the high-voltage device is formed. As a result, the drive-in process is not required when the logic N-well 110 and the logic P-well 112 are formed; thus, the impurities in the logic N-well 110 and the logic P-well 112 are hardly out-diffused out of the substrate 100.

An isolation process such as a shallow trench isolation process or a local oxidation of silicon (LOCOS) process is performed on the substrate 100, thereby forming an isolation layer on the substrate 100 and separating an active region and a field region.

In case that the silicon nitride layer is not removed in a previous step, the silicon nitride layer is necessarily removed from the substrate, subsequent to the formation of the logic N-well 110 and the logic P-well 112. Thereafter, the buffer oxide layer 102 is removed from the substrate 100.

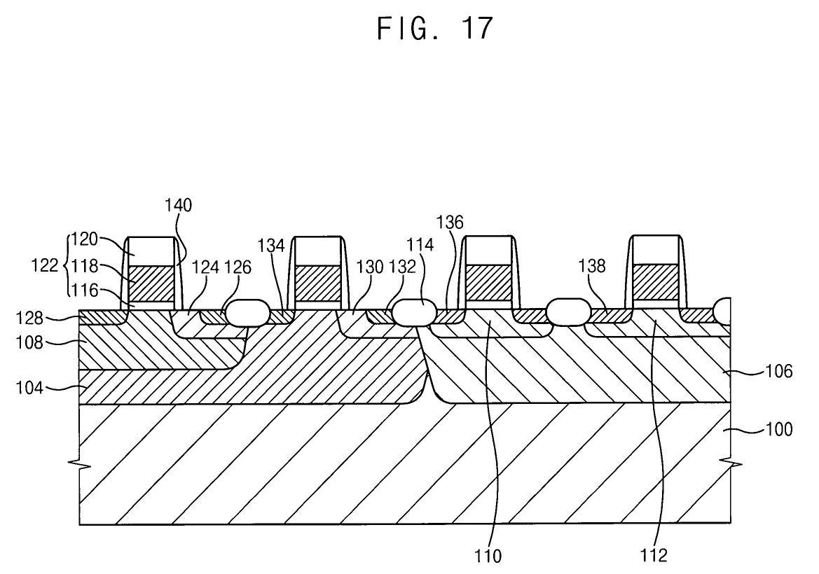

As shown in FIG. 16, the substrate 100 includes which the pocket P-well 108, the N-well 104, the logic N-well 110 and the logic P-well 112. In accordance with at least one embodiment of the invention, a silicon oxide layer (not shown) is formed on the substrate 100 as a gate insulation layer such that the silicon oxide layer corresponding to the high-voltage device region A of the substrate 100 has a thickness greater than that of the silicon oxide layer corresponding to the logic circuit region B of the substrate 100. A gate conductive layer and a hard mask layer are formed on the silicon oxide layer. Then the hard mask layer, the gate conductive layer and the silicon oxide layer are sequentially patterned, thereby forming a gate structure including a silicon oxide pattern 116, a gate conductive pattern 118, and a hard mask pattern 120 stacked on the substrate 100.

As shown in FIG. 17, N type impurities are lightly implanted into the substrate 100 corresponding to the pocket P-well 108, in proximity to a first sidewall of the gate structure 122, thereby forming a first lightly-doped drain region 124, of which the depth is shallower than that of the pocket P-well 108. Then, N type impurities are heavily implanted into the substrate 100 corresponding to the pocket P-well 108, spaced apart from the first sidewall of the gate structure 122, thereby forming a first heavily-doped drain region 126 in the first lightly-doped drain region 124. In forming the first heavily-doped drain region 126, N type impurities are also heavily implanted into the substrate 100 corresponding to the pocket P-well 108, closely to a second sidewall of the gate structure 122, thereby forming a first highly-doped source region 128. The first and second sidewalls of the gate structure 122 on the pocket P-well are completely symmetrical with respect to a central line of the gate structure 122.

In addition, P type impurities are lightly implanted into the substrate 100 corresponding to the N-well 104, in proximity to a first sidewall of the gate structure 122, thereby forming a second lightly-doped drain region 130, of which the depth is shallower than that of the N-well 104. Then, P type impurities are heavily implanted into the substrate 100 corresponding to the N-well 104, spaced apart from the first sidewall of the gate structure 122, thereby forming a second heavily-doped drain region 132 in the second lightly-doped drain region 130. In forming the second heavily-doped drain region 132, P type impurities are also heavily implanted into the substrate 100 corresponding to the N-well 104 closely to a second sidewall of the gate structure 122, thereby forming a second highly-doped source region 134. The first and second sidewalls of the gate structure 122 on the N-well 104 are also completely symmetrical with respect to a central line of the gate structure 122.

P type impurities are implanted into the substrate 100 corresponding to the logic N-well 110, in proximity to both sidewalls of the gate structure 122, thereby forming third source/drain regions 136. N type impurities are implanted into the substrate 100 corresponding to the logic P-well 112, in proximity to both sidewalls of the gate structure 122, thereby forming fourth source/drain regions 138. It should be appreciated that a spacer 140 may be further formed on both sidewalls of the gate structure 122 before the impurities are highly implanted into the substrate 100.

Accordingly, a semiconductor device is formed to have a high-voltage device and a logic device, and an out-diffusion of the impurities is prevented or substantially prevented in forming a well having a low concentration of impurities for the high-voltage device.

According to various exemplary embodiments of the present invention, a diffusion barrier layer is formed prior to the drive-in process for a deep well having a low concentration of impurities in a substrate, thereby minimizing or preventing an out-diffusion of the impurities from a substrate. As a result, the concentration profile of the impurities in the well is maintained unchanged or substantially unchanged, thereby preventing or minimizing deterioration of electrical characteristics of the desired transistor. In addition, the contamination of the apparatus for performing the drive-in diffusion process through an out-diffusion of impurities is prevented.

While the exemplary embodiments of the present invention have been described in detail for the purpose of illustration, it is understood that the present invention should not be construed as limited thereby. It will be readily apparent to those skilled in the art that various changes and modifications to the foregoing exemplary embodiments can be made without departing from the spirit and scope of the invention as defined by the appended claims.

What is claimed is:

1. A method of forming a well in a substrate of a transistor for a semiconductor device, comprising:
implanting a first conductivity type impurity into the substrate;
implanting a second conductivity type impurity opposite to the first conductivity type impurity into a portion of the substrate, thereby forming a first conductivity type impurity region and a second conductivity type impurity region in the substrate;
forming a diffusion barrier layer on the substrate; and
heat-treating the substrate for diffusing the first and second conductivity type impurities from the first and second conductive impurity regions, respectively, thereby forming a first conductivity type well and a second conductivity type well in the substrate.

2. The method of claim 1, further comprising, prior to implanting the first conductivity type impurity into the substrate, forming a buffer oxide layer on the substrate.

3. The method of claim 1, wherein implanting the second conductivity type impurity into the portion of the substrate includes:
forming a photoresist pattern on the substrate to selectively expose the portion of the substrate;
implanting the second conductivity type impurity into the portion of the substrate using the photoresist pattern as an implantation mask; and
removing the photoresist pattern from the substrate.

4. The method of claim 1, wherein the diffusion barrier layer comprises a silicon nitride layer.

5. The method of claim 4, wherein the thickness of the silicon nitride layer is in the range of about 50 Å to about 3000 Å.

6. The method of claim 1, wherein the first conductivity type impurity is an N type impurity and the second conductivity type impurity is a P type impurity.

7. The method of claim 6, wherein the P type impurity comprises boron (B).

8. The method of claim 1, wherein the substrate is heat-treated at a temperature of about 800° C. to about 1300° C. for about 70 minutes.

9. The method of claim 1, wherein the first conductivity type well and the second conductivity type well each have a depth of about 1 μm to about 12 μm from a surface of the substrate.

10. The method of claim 1, further comprising:
re-implanting the second conductivity type impurity into an upper portion of the first conductivity type well in the substrate; and
heat-treating the substrate for diffusing the re-implanted second conductivity type impurity, thereby forming a second conductivity type pocket well in the first conductivity type well.

11. The method of claim 10, further comprising removing the diffusion barrier layer from the substrate subsequent to forming the second conductivity type pocket well.

12. A method of forming a well in a substrate of a transistor for a semiconductor device, comprising:
implanting a first conductivity type impurity into the substrate;
forming a diffusion barrier layer on the substrate;
implanting a second conductivity type impurity opposite to the first conductivity type impurity into a portion of the substrate, thereby forming a first conductivity type impurity region and a second conductivity type impurity region in the substrate; and
heat-treating the substrate for diffusing the first and second conductivity type impurities from the first and second conductivity type impurity regions, respectively, thereby forming a first conductivity type well and a second conductivity type well in the substrate.

13. The method of claim 12, wherein the diffusion barrier layer comprises a silicon nitride layer.

14. The method of claim 13, wherein the thickness of the silicon nitride layer is in the range of about 50 Å to about 3000 Å.

15. A method of forming a well in a substrate of a transistor for a semiconductor device, comprising:
forming a diffusion barrier layer on the substrate;
implanting a first conductivity type impurity into the substrate including the diffusion barrier layer;
implanting a second conductivity type impurity opposite to the first conductivity type impurity into a portion of the substrate, thereby forming a first conductivity type impurity region and a second conductivity type impurity region in the substrate; and
heat-treating the substrate for diffusing the first and second conductivity type impurities from the first and second conductivity type impurity regions, respectively, thereby forming a first conductivity type well and a second conductivity type well in the substrate.

16. The method of claim 15, wherein the diffusion barrier layer comprises a silicon nitride layer.

17. The method of claim 16, wherein the thickness of the silicon nitride layer is in the range of about 50 Å to about 3000 Å.

18. The method of claim 1, further comprising:
re-implanting the second conductivity type impurity into an upper portion of the first conductivity type well in the substrate;
additionally heat-treating the substrate for diffusing the re-implanted second conductivity type impurity, thereby forming a second conductivity type pocket well in the first conductivity type well; and
forming a plurality of transistors on the substrate corresponding to the second conductivity type well, the first conductivity type well and the second conductivity type pocket well, respectively.

19. The method of claim 18, wherein the diffusion barrier layer comprises a silicon nitride layer.

20. The method of claim 19, wherein the thickness of the silicon nitride layer is in the range of about 50 Å to about 3000 Å.

21. The method of claim 18, wherein the first conductivity type well and the second conductivity type well each have a depth of about 1 μm to 12 μm from a surface of the substrate.

22. The method of claim 18, wherein the transistor includes a high-voltage metal oxide semiconductor (MOS) transistor.
